(19) United States
(12) Patent Application Publication
(10) Pub. No.: US 2026/0371953 A1
(43) Pub. Date: Nov. 19, 2026

(54) METHOD FOR SELECTIVELY FORMING A FILM AND REACTION SYSTEM FOR THE SAME

(71) Applicant: ASM IP Holding B.V., Almere (NL)

(72) Inventors: Annisa Noorhidayati, Tokyo (JP); Musa Alaydrus, Helsinki (FI); Hiroki Matsuda, Tokyo (JP); Agung Setiadi, Tokyo (JP)

(21) Appl. No.: 19/673,217

(22) Filed: May 11, 2026

Related U.S. Application Data
(60) Provisional application No. 63/805,677, filed on May 14, 2025.

(51) Int. Cl. H10P 14/60; C23C 16/52; H10P 14/694; H10P 50/68

(52) U.S. Cl. CPC H10P 14/6336; C23C 16/52; H10P 14/6514; H10P 14/6534; H10P 14/69433; H10P 50/683

(57) ABSTRACT

A method for selectively forming a film is provided. The method includes providing a substrate in a reaction chamber. The substrate includes a first horizontal surface and a gap feature extending downwardly from the first horizontal surface. The method includes depositing a material layer on the first horizontal surface and in the gap feature through a deposition process. The method includes removing the material layer on the first horizontal surface and the material layer on a second horizontal surface of a bottom portion of the gap feature through an etching process to selectively form a film on a vertical sidewall of the gap feature.

### CROSS-REFERENCE TO RELATED APPLICATIONS

This application claims priority to U.S. Provisional Patent Application Ser. No. 63/805,677 filed May 14, 2025 titled METHOD FOR SELECTIVELY FORMING A FILM AND REACTION SYSTEM FOR THE SAME, the disclosure of which is hereby incorporated by reference in its entirety.

### BACKGROUND

### Technical Field

The present disclosure is related to a method for forming a film. More particularly, it is related to a method for selectively forming a film on sidewalls of a gap feature using plasma.

### Background

In the manufacturing processes of integrated circuits, there are several processes used for forming sidewalls in gap features. The sidewalls are used as spacers or for blocking the etching of a structure from side surfaces of gap features. Conventionally, the sidewalls are formed by forming a conformal film on the surfaces of gap features, and then removing the portions formed on the upper surface in which the gap features are formed, as well as the portions formed on the bottom surfaces of the gap features, using asymmetrical etching. However, when such a formation method is used, over-etching is required in order to remove footing from sidewalls. Over-etching causes etching of an underlying layer, damaging the layer. In addition, in gap features with depth from a few nanometers to a few micrometers, it is hard to achieve a continuous film formed on the vertical sidewalls of the gap features without the formation on the horizontal surfaces of the gap features. Therefore, the development of selectively forming a film on a substrate is required.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### SUMMARY

This summary is provided to introduce a selection of concepts in a simplified form. These concepts are described in further detail in the detailed description of embodiments of the disclosure below. This summary is not intended to identify key features or essential features of the claimed subject matter, nor is it intended to be used to limit the scope of the claimed subject matter.

According to some embodiments of the present disclosure, a method for selectively forming a film is provided. The method includes providing a substrate in a reaction chamber. The substrate includes a first horizontal surface and a gap feature extending downwardly from the first horizontal surface. The method includes depositing a material layer on the first horizontal surface and in the gap feature through a deposition process. The method includes removing the material layer on the first horizontal surface and the material layer on a second horizontal surface of a bottom portion of the gap feature through an etching process to selectively form a film on a vertical sidewall of the gap feature.

In some embodiments, a first plasma is provided in the reaction chamber during the deposition process.

In some embodiments, the first plasma comprises a single-frequency plasma.

In some embodiments, the first plasma comprises a combination of a first sub-plasma and a pulsed second sub-plasma, and the first sub-plasma is different from the pulsed second sub-plasma.

In some embodiments, a first plasma and a co-reactant are provided in the reaction chamber during the deposition process.

In some embodiments, the first plasma comprises a single-frequency plasma, and the co-reactant comprises H₂, Ar, or a combination thereof.

In some embodiments, the first plasma comprises a combination of a first sub-plasma and a pulsed second sub-plasma, the co-reactant comprises H₂, Ar, or a combination thereof, and the first sub-plasma is different from the pulsed second sub-plasma.

In some embodiments, in the etching process, the etching rate of the material layer on the second horizontal surface of the bottom portion of the gap feature is about twice the etching rate of the material layer on the vertical sidewall of the gap feature.

In some embodiments, further comprising performing a treatment process after the deposition process and before the etching process.

In some embodiments, a first plasma is provided in the reaction chamber during the deposition process, a second plasma is provided in the reaction chamber during the treatment process, and the first plasma is different from the second plasma.

In some embodiments, the second plasma comprises a combination of a first sub-plasma and a second sub-plasma, and the first sub-plasma is different from the second sub-plasma.

In some embodiments, a co-reactant is provided in the reaction chamber during the treatment process, and the co-reactant comprises H₂, Ar, or a combination thereof.

In some embodiments, in the etching process, the etching rate of the material layer on the second horizontal surface of the bottom portion of the gap feature is about 3 times the etching rate of the material layer on the vertical sidewall of the gap feature.

In some embodiments, the first plasma comprises a first combination of a first sub-plasma and a second sub-plasma, the second plasma comprises a second combination of a third sub-plasma and a fourth sub-plasma, and the first sub-plasma, the second sub-plasma, the third sub-plasma and the fourth sub-plasma are different.

In some embodiments, the second sub-plasma of the first combination of the first plasma is a pulsed plasma.

In some embodiments, a co-reactant is provided in the reaction chamber during the treatment process, and the co-reactant comprises H₂, Ar, or a combination thereof.

In some embodiments, in the etching process, the etching rate of the material layer on the second horizontal surface of the bottom portion of the gap feature is about 4 times the etching rate of the material layer on the vertical sidewall of the gap feature.

In some embodiments, the frequency of the first plasma is greater than the frequency of the second plasma.

In some embodiments, the first plasma densifies the material layer on the vertical sidewall of the gap feature.

In some embodiments, the second plasma damages the material layer on the first horizontal surface and the material layer on the second horizontal surface of the bottom of the gap feature such that the material layer on the first horizontal surface and the material layer on the second horizontal surface of the bottom of the gap feature are removed during the etching process.

According to some embodiments of the present disclosure, a reaction system is provided. The system includes a reaction chamber, a substrate support, a precursor source, a co-reactant source, a plasma power source and a controller. The substrate support is disposed in the reaction chamber and is configured to support a substrate. The precursor source provides a precursor into the reaction chamber. The co-reactant source provides a co-reactant into the reaction chamber. The plasma power source provides a plasma into the reaction chamber. The controller is configured to control the precursor, the co-reactant, and the plasma so as to perform the methods of some embodiments of the present disclosure.

### BRIEF DESCRIPTION OF THE DRAWINGS

Embodiments of the present disclosure can be best understood from the following detailed description in conjunction with the accompanying drawings. It should be noted that, in accordance with the common practice in the industry, various features are not drawn to scale. In fact, the dimensions of the various elements may be arbitrarily increased or reduced to clearly illustrate the features of the embodiments of the present disclosure. It should also be noted that the drawings illustrate typical embodiments of the present disclosure. The drawings should not be considered as limitation of the present disclosure. The present disclosure may also be applied to other embodiments.

FIG. 1 illustrates a schematic method for selectively forming a film on a substrate according to some embodiments of the present disclosure.

FIG. 2 illustrates a schematic cross-section of a substrate having a gap feature, according to some embodiments of the present disclosure.

FIG. 3 illustrates a schematic method for selectively forming a film on a substrate, according to some embodiments of the present disclosure.

FIG. 4 illustrates a schematic timing sequence, according to some embodiments of the present disclosure.

FIG. 5 illustrates a schematic timing sequence, according to some embodiments of the present disclosure.

FIG. 6 illustrates a schematic timing sequence, according to some embodiments of the present disclosure.

FIG. 7 illustrates a schematic timing sequence, according to some embodiments of the present disclosure.

FIG. 8 illustrates a schematic reaction system for selectively forming a film on a substrate, according to some embodiments of the present disclosure.

### DETAILED DESCRIPTION

The following disclosure provides many different embodiments, or examples, for implementing different features of the described subject matter. Specific examples of elements and arrangements are described below to simplify the present description. These are, of course, merely examples and are not intended to be limiting. For example, a formation of a first feature over or on a second feature in the description that follows may include embodiments in which the first and second features are formed in direct contact, and may also include embodiments in which additional features may be formed between the first and second features, such that the first and second features may not be in direct contact. Furthermore, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be inter-preted accordingly.

It should be understood that the ordinal numbers used in the present disclosure, such as the terms “first,” “second,” “third,” etc., are used to modify an element, which itself does not mean and represent that the element (or elements) has any previous ordinal number, and does not mean the order of a certain element and another element, or the order in the manufacturing method. The use of these ordinal numbers is to make an element with a certain name can be clearly distinguished from another element with the same name. The claims and the specification may not use the same terms. For example, the first element in the specification may refer to the second element in the claims.

In the following descriptions, terms “about” and “substantially” typically mean +/−10% of the stated value, or typically +/−5% of the stated value, or typically +/−3% of the stated value, or typically +/−2% of the stated value, or typically +/−1% of the stated value or typically +/−0.5% of the stated value. The expression “in a range from the first value to the second value” or “between the first value and the second value” means that the range includes the first value, the second value, and other values in between. The values given in the present disclosure are approximate. That is, without specifying terms the terms “about” and “substantially,” the meaning of “about” and “substantially” can still be implied.

Some embodiments of the present disclosure are described below. Additional steps or operations may be provided before, during, and/or after the steps or operations described in these embodiments. Some of the steps or operations described may be replaced or deleted in different embodiments. In addition, it should be understood that in the following embodiments, without departing from the spirit of the present disclosure, the features in several different embodiments can be replaced, recombined, and mixed to complete another embodiment. The features between the various embodiments can be mixed and matched arbitrarily as long as they do not violate or conflict the spirit of the present disclosure.

In the present disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, a multi-port injection system, other gas distribution device, or the like, can be used for, e.g., sealing the reaction space, and can include a seal gas, such as a noble gas. In some cases, the term “precursor” can refer to a compound that participates in the chemical reaction that produces another compound, and particularly to a compound that constitutes a film matrix or a main skeleton of a film. The term “reactant” can be used interchangeably with the term “precursor.”

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

For example, a substrate in the form of a powder may have applications for pharma-ceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

A non-limiting example of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

As used herein, “atomic layer deposition,” abbreviated as “ALD,” refers to a vapor deposition process in which deposition cycles, such as a plurality of consecutive deposition cycles, are conducted in a reaction space (i.e., one or more reaction chambers). Generally, in ALD processes, during each deposition cycle, a precursor is introduced into a reaction space and is adsorbed onto a substrate surface, which may include a previously deposited material from a previous ALD cycle or other materials, forming maximally one monolayer of the precursor that does not readily react with additional excess precursor (i.e., a self-limiting reaction). Thereafter, in some cases, another precursor or a reactant may be introduced into the reaction space to convert the chemisorbed precursor to the desired material on the substrate surface. Other reaction steps may be included in the deposition cycle. ALD may occur by a thermal process (thermal ALD), where the reactions are promoted by increasing the temperature of the substrate relevant to ambient temperature; and/or by a plasma enhanced process (PEALD), where the reactions are promoted through the use of energetic plasma species. ALD, as used herein, may also be meant to include processes designated by related terms, such as chemical vapor atomic layer deposition, atomic layer epitaxy (ALE), molecular beam epitaxy (MBE), gas source MBE, or organometallic MBE, and chemical beam epitaxy when performed with alternating pulses of reactants.

As used herein, “chemical vapor deposition,” abbreviated as “CVD,” refers to a vapor deposition process in which a film is deposited on a substrate by exposing its surface to one or more gaseous precursors and reactants, which react and/or decompose on the substrate surface to form the film. The precursors and/or reactants can be provided simultaneously to the reaction space, or in partially or completely separated pulses. In some embodiments, the precursors and/or reactants are provided until a layer having a desired thickness is deposited. In some embodiments, a cyclic CVD process can be used with multiple cycles to deposit a thin film having a desired thickness. In cyclic CVD processes, the precursors and/or reactants may be provided to the reaction space in pulses that do not overlap, or that partially or completely overlap. CVD may occur by a thermal process (thermal CVD), where the reactions are promoted by increasing the temperature of the substrate relevant to ambient temperature; or by a plasma enhanced process (PECVD), where the reactions are promoted through the use of energetic plasma species.

As used herein, the term “film” and/or “layer” can refer to any continuous or non-continuous structures and material, such as material deposited by the methods disclosed herein. For example, film and/or layer can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous. Alternatively, a film or layer may consist entirely of isolated islands.

In the present disclosure, the terms “including,” “constituted by” and “having” refer independently to “typically or broadly comprising,” “comprising,” “consisting essentially of,” or “consisting of” in some embodiments. It shall be understood that when a composition, method, device, etc. is said to comprise certain features, it means that it includes those features, and that it does not necessarily excludes the presence of other features, as long as they do not render the claim unworkable. This notwithstanding, the wording “comprises” includes the meaning of “consists of,” i.e., the case when the composition, method, device, etc. in question only includes the features, components, and/or steps that are listed, and does not contain any other features, components, steps, etc.

The term “carrier gas” as used herein may refer to a gas that is provided to a reaction chamber together with one or more precursors. For example, a carrier gas may be provided to the reaction chamber together with one or more of the precursors used herein. Exemplary carrier gasses include N₂, H₂, and noble gasses such as He, Ne, Kr, Ar, and Xe.

As opposed to a carrier gas, a purge gas may be provided to a reaction chamber separately, i.e., not together with one or more precursors. This notwithstanding, gasses which are commonly used as carrier gas may also be used as a purge gas, even within the same process. For example, in a cyclic deposition-etch process, N₂ used as a carrier gas may be provided together with one or more precursors during deposition pulses, and N₂ used as a purge gas may be used to separate deposition and etch pulses. Hence, it is the manner of how a gas is provided to the reaction chamber that determines whether it serves as a purge gas or a carrier gas in a specific context. Thus, as used herein, the term “purge” may refer to a procedure in which an inert or substantially inert gas is provided to a reaction chamber in between two pulses of gasses which react with each other. For example, a purge, e.g., using nitrogen gas, may be provided between a precursor pulse and a reactant pulse, thus avoiding or at least minimizing gas phase interactions between the precursor and the reactant. It shall be understood that a purge can be effected either in time or in space, or both. For example, in the case of temporal purges, a purge step can be used, e.g., in the temporal sequence of providing a first precursor to a reaction chamber, providing a purge gas to the reaction chamber, and providing a second precursor to the reaction chamber, wherein the substrate on which a layer is deposited does not move. For example, in the case of spatial purges, a purge step can take the following form: moving a substrate from a first location to which a first precursor is continually supplied, through a purge gas curtain, to a second location to which a second precursor is continually supplied.

Refer to FIG. 1, which illustrates a schematic method 100 for selectively forming a film on a substrate according to some embodiments of the present disclosure. The method 100 includes: providing a substrate in a reaction chamber (step 110); providing a precursor in the reaction chamber (step 120); providing a plasma in the reaction chamber (step 130); and performing an etching process (step 140).

In the step 110, the substrate may be brought to a desired temperature and the reaction chamber may be brought to a desired pressure, such as a temperature and pressure suitable for subsequent steps. By way of examples, a temperature (e.g., of a substrate or a substrate support) within a reaction chamber can be between 350 °C and 450 °C. In some embodiments, the substrate includes one or more gap features, such as trenches.

In the step 120, the precursor for forming the film (material layer) is introduced into the reaction chamber. In some embodiments, the precursor may include a silicon-containing compound and a reactant. In some embodiments, the silicon-containing compound may include at least one of: a silane, a silylamine, an aminosilane, or a halogenated silicon compound. For example, the precursor may include at least one of: silane (SiH₄), disilane (Si₂H₆), trisilane (Si₃H₈), tetrasilane (Si₄H₁₀), N(Si₂H₅)₃, trisilylamine N(SiH₃)₃, N(SiMe₃)(SiHMeNMe₂)₂, 2,2-disilyltrisilane (Si(SiH₃)₄), trisdimethylaminosilane (SiH(NMe₂)₃), bis(diethylamino)silane (SiH₂(NEt₂)₂) (BEDAS), bis(tert-butylamino)silane (SiH₂(NHtBu)₂) (BTBAS), (di-isopropy-lamido)silane (SiH₃(NiPr₂)) (DIPAS), trichloro disilane (Si₂Cl₃H₃), pentachloro disilane (Si₂Cl₅H), hexachloro disilane (Si₂Cl₆), octachlorotrisilane (Si₃Cl₈), dichloro silane (SiCl₂H₂), dimethyldichlorosilane (SiCl₂Me₂), tetrachloro silane (SiCl₄), tetraiodo silane (SiI₄), triiodo silane (SiI₃H) or diiodo silane(SiI₂H₂), where Me represents a methyl group, Et represents an ethyl group, tBu represents a tert-butyl group, and iPr represents an isopropyl group.

In some embodiments, the reactant may include at least one of: N₂, NH₃, a mixture of N₂ and H₂, or a combination thereof. In some embodiments, the film (material layer) may be formed by a deposition process such as CVD, ALD, PECVD (plasma enhanced CVD), PEALD (plasma enhanced ALD), or other suitable deposition process.

In the step 130, the plasma may be provided by a dual frequency plasma source including a very high frequency (VHF) component (VHF plasma) and a low radio frequency (LRF) component (LRF plasma). In some embodiments, the frequency of the VHF component may be, for example, between 30 MHz and 60 MHz, between 35 MHz and 55 MHz, or between 40 MHz and 50 MHz. In an embodiment, the frequency of the VHF component may be 60 MHz. In some embodiments, the frequency of the LRF component may be, for example, between 300 kHz and 500 kHz, or between 350 kHz and 450 kHz. In an embodiment, the frequency of the LRF component may be 430 kHz. In some embodiments, the VHF component may have a power between about 700 watts (W) and about 1250 watts. In some embodiments, the LRF component may have a power between about 20 watts and about 500 watts, or between about 100 watts and about 500 watts.

In the step 140, the etching process may be a wet etching process. In some embodiments, an etchant may be a dilute hydrofluoric acid (dHF).

It should be noted that the sequence of the steps in the method 100 is only an example. The sequence may be varied in other embodiments. In some embodiments, other steps may be provided in the method. For example, in some embodiments, there is an additional step for providing a second precursor. For example, in some embodiments, there is an additional step for providing a purge gas or a carrier gas.

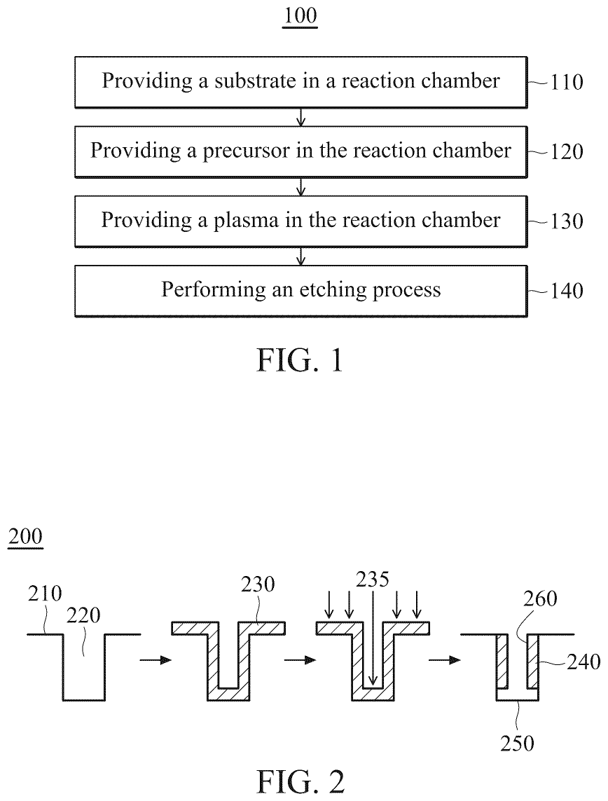

Refer to FIG. 2, which illustrates a schematic cross-section of a substrate having a gap feature according to some embodiments of the present disclosure. The substrate 200 includes a first horizontal surface 210 and a gap feature 220 extending downwardly from the first horizontal surface 210. A material layer 230 is deposited on the first horizontal surface 210 and in the gap feature 220 through a deposition process (step 120). The plasma 235 is provided to densify the material layer 230 on the vertical sidewall 240 of the gap feature 220 and damage the material layer 230 on the first horizonal surface 210 of the substrate and the material layer 230 on a second horizontal surface 250 of the bottom portion of the gap feature 220 (step 130). In some embodiments, the plasma is a single-frequency plasma (e.g., VHF plasma). In some embodiments, the plasma includes a combination of the VHF plasma and the pulsed LRF plasma. The etching process is performed to remove the material layer 230 on the first horizontal surface 210 and the material layer 230 on the second horizontal surface 250 of the bottom portion of the gap feature 220 to selectively form a film 260 on the vertical sidewall 240 of the gap feature 220. In some embodiments, the material layer 230 and the film 260 may include SiN.

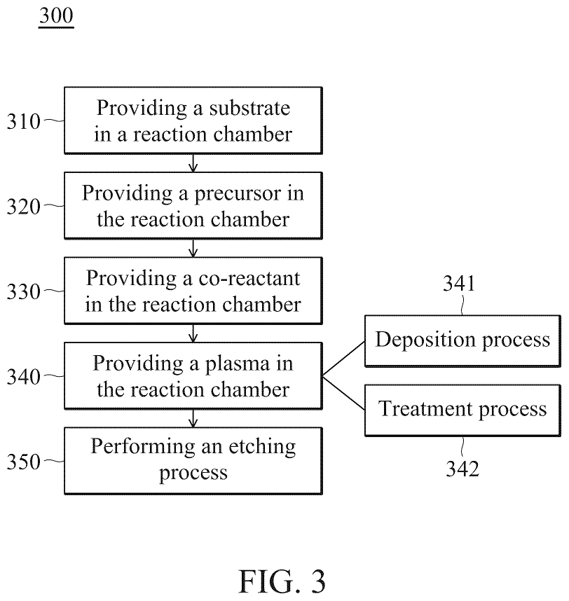

Refer to FIG. 3, which illustrates a schematic method 300 for selectively forming a film on a substrate according to some embodiments of the present disclosure. The method 300 includes: providing a substrate in a reaction chamber (step 310); providing a precursor in the reaction chamber (step 320); providing a co-reactant in the reaction chamber (step 330); providing a plasma in the reaction chamber (step 340); and performing an etching process (step 350).

The step 310 is similar to the step 110, the step 320 is similar to the step 120, and the step 350 is similar to the step 140. Therefore, it is not repeated again herein.

In step 330, the co-reactant including H₂, Ar, or a combination thereof may be pro vided in the reaction chamber to enhance the etching selectivity of the material layer during the deposition process.

In some embodiments, the plasma provided in step 340 is a single-frequency plasma (e.g., VHF plasma) during the deposition process (step 341). In some embodiments, a plasma including N₂ may be used during the deposition process. In some embodiments, the plasma provided in step 340 includes a combination of the VHF plasma and the pulsed LRF plasma during the deposition process (step 341).

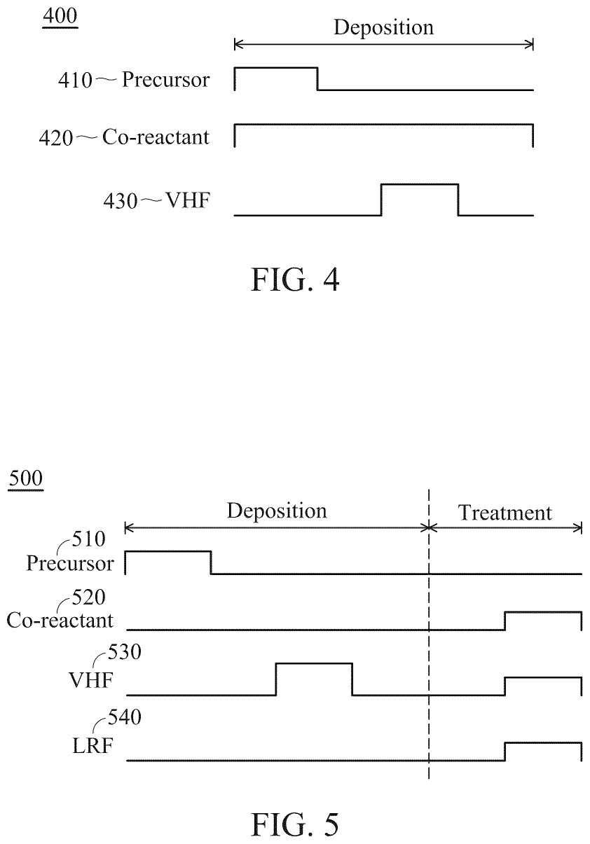

Refer to FIG. 4, which illustrates a schematic timing sequence 400 according to some embodiments of the present disclosure. The timing sequence 400 includes a precursor 410, a co-reactant 420, and a VHF plasma 430. During the deposition process, the precursor 410 is provided before the VHF plasma 430, and the co-reactant 420 is provided continuously for the whole sequence.

In the embodiment as shown in FIG. 4, the VHF plasma 430 is the single-frequency plasma, and the co-reactant 420 is Ar. The etching rate (e.g. wet etching rate) of the material layer 230 on the second horizontal surface 250 of the bottom portion of the gap feature 220 is about twice the etching rate (e.g. wet etching rate) of the material layer 230 on the vertical sidewall 240 of the gap feature 220.

In some embodiments, the plasma provided in step 340 includes a first plasma and a second plasma. The first plasma is different from the second plasma. The first plasma is provided in the reaction chamber during the deposition process (step 341), and the second plasma is provided in the reaction chamber during a treatment process (step 342). The treatment process (step 342) is performed after the deposition process (step 341) and before the etching process (step 350).

Refer to FIG. 5, which illustrates a schematic timing sequence 500 according to some embodiments of the present disclosure. The timing sequence 500 includes a precursor 510, a co-reactant 520, a VHF plasma 530, and a LRF plasma 540. The precursor 510 is provided before the VHF plasma 530 during the deposition process, and the co-reactant 520, the VHF plasma 530, and the LRF plasma 540 are provided during the treatment process.

In the embodiment as shown in FIG. 5, the first plasma is the VHF plasma 530 during the deposition process, and the second plasma includes a combination of the VHF plasma 530 and the LRF plasma 540 during the treatment process. In this embodiment, the co-reactant 520 including H₂ is provided in the reaction chamber during the treatment process. The etching rate (e.g. wet etching rate) of the material layer 230 on the second horizontal surface 250 of the bottom portion of the gap feature 220 is about 3 times the etching rate (e.g. wet etching rate) of the material layer 230 on the vertical sidewall 240 of the gap feature 220.

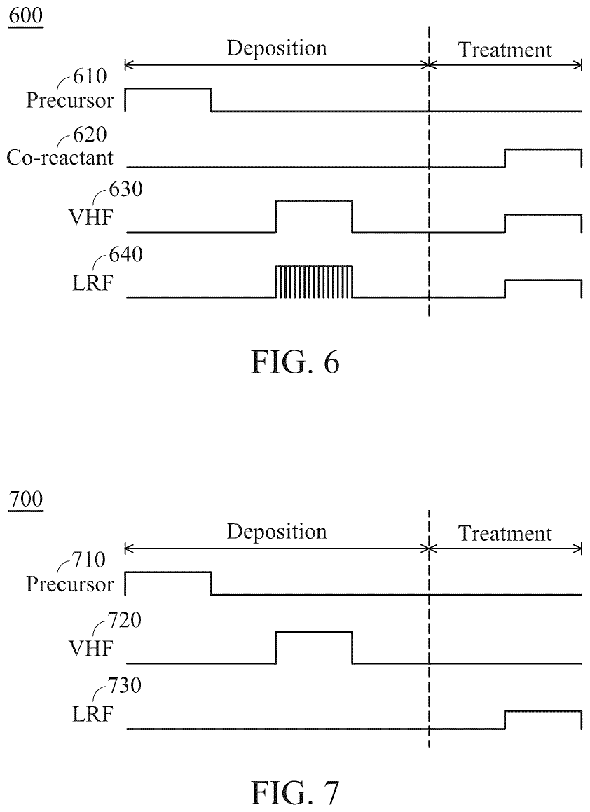

Refer to FIG. 6, which illustrates a schematic timing sequence 600 according to some embodiments of the present disclosure. The timing sequence 600 includes a precursor 610, a co-reactant 620, a VHF plasma 630 and a LRF plasma 640. The precursor 610 is provided before the VHF plasma 630 and the LRF plasma 640 during the deposition process, and the co-reactant 620, the VHF plasma 630, and the LRF plasma 640 are provided during the treatment process.

In the embodiment as shown in FIG. 6, the first plasma includes a first combination of the VHF plasma 630 and the LRF plasma 640 during the deposition process, and the second plasma includes a second combination of the VHF plasma 630 and the LRF plasma 640 during the treatment process. The first combination is different from the second combination. The LRF plasma 640 of the first combination of the first plasma is a pulsed plasma. The frequency of the pulse is about 2.5 kHz. In this embodiment, the co-reactant including H₂ is provided in the reaction chamber during the treatment process. The etching rate (e.g. wet etching rate) of the material layer 230 on the second horizontal surface 250 of the bottom portion of the gap feature 220 is about 4 times the etching rate (e.g. wet etching rate) of the material layer 230 on the vertical sidewall 240 of the gap feature 220.

Refer to FIG. 7, which illustrates a schematic timing sequence 700 according to some embodiments of the present disclosure. The timing sequence 700 includes a precursor 710, a VHF plasma 720, and a LRF plasma 730. The precursor 710 is provided before the VHF plasma 720 during the deposition process, and the LRF plasma 730 is provided during the treatment process.

In the embodiment as shown in FIG. 7, the first plasma is the VHF plasma 720 during the deposition process, and the second plasma is the LRF plasma 730 during the treatment process. In this embodiment, the etching rate (e.g. wet etching rate) of the material layer 230 on the second horizontal surface 250 of the bottom portion of the gap feature 220 is about 4 times the etching rate (e.g. wet etching rate) of the material layer 230 on the vertical sidewall 240 of the gap feature 220.

It should be noted that the timing sequences 400, 500, 600, and 700 are examples. The duration and starting point of the precursor, the co-reactant, the VHF plasma, and/or the LRF plasma may be varied in other embodiments. For example, in some embodiments, the co-reactant 420, 520, and 620 may be continuous. In other embodiments, the co-reactant 420, 520, and 620 may be pulsed. In some embodiments, the VHF plasma 430, 530, 630, and 720 may be continuous. In other embodiments, the VHF plasma 430, 530, 630, and 720 may be pulsed. In some embodiments, the LRF plasma 540, 640, and 730 may be continuous. In other embodiments, the LRF plasma 540, 640, and 730 may be pulsed.

In some embodiments, a first selectivity (selectivity 1) is defined by: (the wet etching rate of the material layer 230 on the second horizontal surface 250 of the bottom portion of the gap feature 220)/(the wet etching rate of the material layer 230 on the vertical sidewall 240 of the gap feature 220 at the height of 90 mm from the second horizontal surface 250). A second selectivity (selectivity 2) is defined by: (the wet etching rate of the material layer 230 on the second horizontal surface 250 of the bottom portion of the gap feature 220)/(the wet etching rate of the material layer 230 on the vertical sidewall 240 of the gap feature 220 at the height of 120 mm from the second horizontal surface 250). The etchant of the etching process may be dilute hydrofluoric acid (dHF).

In some embodiments, a VHF plasma is provided during the deposition process of the material layer, and a co-reactant and a LRF plasma are not provided during the deposition process. In some embodiments, a VHF plasma and a co-reactant are provided during the deposition process of the material layer, and a LRF plasma is not provided during the deposition process. In some embodiments, a first VHF plasma is provided during the deposition process of the material layer, and a second VHF plasma, a LRF plasma, and a co-reactant are provided during the treatment process. In some embodiments, a VHF plasma is provided during the deposition process of the material layer, and a LRF plasma is provided during the treatment process. In some embodiments, a first VHF plasma and a first LRF plasma are provided during the deposition process of the material layer, and a second VHF plasma, a second LRF plasma, and a co-reactant are provided during the treatment process. In some embodiments, the LRF plasma is pulsed, and the frequency of the pulse may be between 1 kHz and 10 kHz, between 2.5 kHz and 7.5 kHz, or between 3 kHz and 6 kHz.

In some embodiments, the power of the VHF plasma may be between 500 W and 1800 W, between 1000 W and 1500 W, or between 700 W and 1250 W. In some embodiments, the power of the LRF plasma may be between 10 W and 700 W, between 20 W and 500 W, or between 50 W and 100 W.

In some embodiments, the co-reactant may be Ar, H₂, or a combination thereof. In some embodiments, the flow of the co-reactant may be between 1 slm (standard liter per minute) and 10 slm, between 2 slm and 8 slm, or between 3 slm and 6 slm. In some embodiments, the flow of the co-reactant may be between 100 sccm (standard cubic centime-ter per minute) and 600 sccm, between 200 sccm and 500 sccm, or between 300 sccm and 400 sccm.

In some embodiments, the selectivity 1 may be between 1.0 and 4.0, between and 4.0, between 2.2 and 4.0, or between 3.9 and 4.0 in the etching process. In some embodiments, the selectivity 2 may be between 1.0 and 4.4, between 2.1 and 4.4, between 3.2 and 4.4, or between 4.1 and 4.4 in the etching process.

In some embodiments, the selectivity may be increased by about 4.0, about 4.1, or about 4.4. The higher the selectivity, the better the capability of removing the material layer on the horizontal surface and forming the material layer on the vertical sidewall of the gap feature.

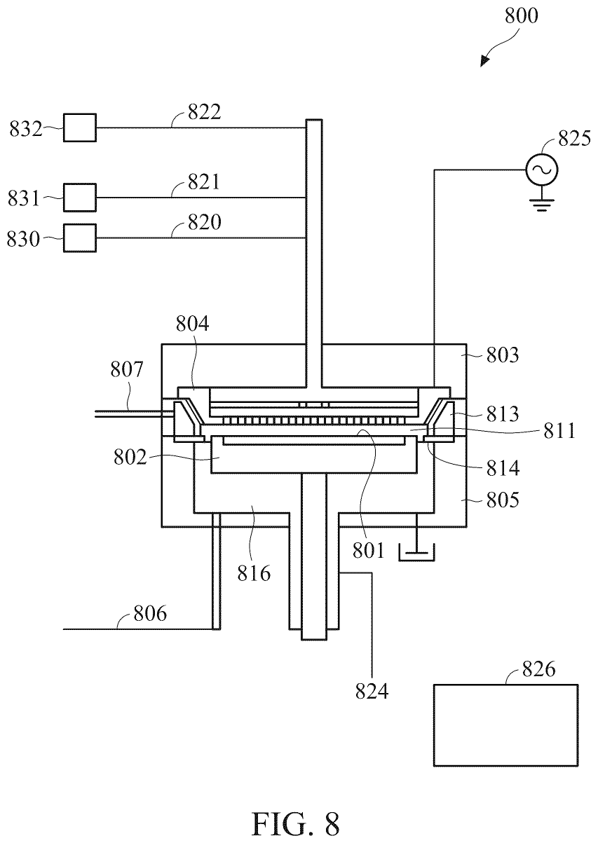

Refer to FIG. 8, which illustrates a reaction system for selectively forming a film on a substrate, according to some embodiments of the present disclosure. The reaction system 800 can be used to perform one or more steps or sub steps as described herein and/or to form one or more structures or portions thereof as described herein.

The reaction system 800 may include a pair of electrically conductive flat-plate electrodes 802, 804 in parallel and facing each other in an interior 811 (reaction zone) of a reaction chamber 803. A plasma can be excited within the reaction chamber 803 by applying VHF power (e.g., 60 MHz) and LRF power (e.g. 430 kHz) from a plasma power source 825 to one electrode (e.g., electrode 804) and electrically grounding the other electrode (e.g., electrode 802). A temperature regulator may be provided in the lower electrode 802, and a temperature of a substrate 801 placed thereon may be kept at a desired temperature. The electrode 802 may serve as a substrate support. The electrode 804 may serve as a gas distribution device, such as a shower plate. Precursor gas from a precursor source 830, co-reactant gas from a co-reactant source 831, if any, purge gas from a purge source 832, and/or the like may be introduced into reaction chamber 803 using one or more of a gas line 820, a gas line 821, and a gas line 822, respectively, and through the electrode 804 (shower plate). Although illustrated with three gas lines, the reaction system 800 may include any suitable number of gas lines.

In the reaction chamber 803, a circular duct 813 with an exhaust line 807 may be provided, through which gas in the interior 811 of the reaction chamber 803 may be exhausted. Additionally, a transfer chamber 805, disposed below the reaction chamber 803, may be provided with a seal gas line 824 to introduce seal gas into the interior 811 of the reaction chamber 803 via the interior 816 (transfer zone) of the transfer chamber 805, wherein a separation plate 814 for separating the reaction zone and the transfer zone may be provided (a gate valve through which a wafer is transferred into or from the transfer chamber 805 is omitted from this figure). The transfer chamber may be also provided with an exhaust line 806. In some embodiments, the deposition and treatment steps may be performed in the same reaction space, so that two or more (e.g., all) of the steps can continuously be conducted without exposing the substrate to air or other oxygen-containing atmosphere.

In some embodiments, continuous flow of an inert or carrier gas to the reaction chamber 803 can be accomplished using a flow-pass system (FPS), wherein a carrier gas line may be provided with a detour line having a precursor reservoir (bottle), and the main line and the detour line may be switched, wherein when only a carrier gas may be intended to be fed to a reaction chamber, the detour line is closed, whereas when both the carrier gas and a precursor gas are intended to be fed to the reaction chamber, the main line may be closed and the carrier gas may flow through the detour line and flow out from the bottle together with the precursor gas. In this way, the carrier gas may continuously flow into the reaction chamber, and may carry the precursor gas in pulses by switching between the main line and the detour line, without substantially fluctuating pressure of the reaction chamber.

The reaction system 800 includes one or more controllers 826 programmed or otherwise configured to cause one or more method steps as described herein to be conducted. The controllers are communicated with the various power sources, heating systems, pumps, robotics and gas flow controllers, or valves of the reactor, as will be appreciated by the skilled artisan.

In some embodiments, a multiple chamber reactor (two or more sections or compart-ments for processing wafers disposed close to each other) can be used, wherein a reactant gas and a noble gas can be supplied through a shared line, whereas a precursor gas is supplied through unshared lines.

According to some embodiments of the present disclosure, the plasma (including the VHF plasma and the LRF plasma) and the co-reactant (including H₂, and Ar) are used to achieve the desired selectivity of the film. Ion direction can be controlled through different combinations of the VHF plasma and the LRF plasma to densify the film on the vertical sidewall of the gap feature and damage the film on the horizonal surface of the substrate and the film on the horizontal surface of the bottom portion of the gap feature. In addition, the combination of the continuous plasma and the pulsed plasma can help control the ion direction so that the ions reach the horizontal surface of the gap feature in great depth. The co-reactant can increase ion flux during the deposition and/or treatment process to help achieve the desired selectivity. As a result, the selectivity of the film can be controlled to selectively form the film on the vertical sidewall of the gap feature instead of on the horizontal surface of the substrate and the horizontal surface of the bottom portion of the gap feature.

Although some embodiments of the present disclosure and their advantages have been described in detail, it should be understood that various changes, substitutions and alterations can be made herein without departing from the spirit and scope of the present disclosure as defined by the appended claims. The features of the various embodiments can be used in any combination as long as they do not depart from the spirit and scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Thus, the appended claims are intended to include within their scope such processes, machines, manufacture, compositions of matter, means, methods or steps. Moreover, each claim constitutes an individual embodiment, and the claimed scope of the present disclosure includes the combinations of the claims and embodiments. The scope of protection of the present disclosure is subject to the definition of the scope of the appended claims. Any embodiment or claim of the present disclosure does not need to meet all the purposes, advantages, and features disclosed in the present disclosure.

What is claimed is:

1. A method for selectively forming a film, comprising:
providing a substrate in a reaction chamber, wherein the substrate comprises a first horizontal surface and a gap feature extending downwardly from the first horizontal surface;
depositing a material layer on the first horizontal surface and in the gap feature through a deposition process; and
removing the material layer on the first horizontal surface and the material layer on a second horizontal surface of a bottom portion of the gap feature through an etching process to selectively form a film on a vertical sidewall of the gap feature.

2. The method for selectively forming the film of claim 1, wherein a first plasma is provided in the reaction chamber during the deposition process.

3. The method for selectively forming the film of claim 2, wherein the first plasma comprises a single-frequency plasma.

4. The method for selectively forming the film of claim 2, wherein the first plasma comprises a combination of a first sub-plasma and a pulsed second sub-plasma, and the first sub-plasma is different from the pulsed second sub-plasma.

5. The method for selectively forming the film of claim 1, wherein a first plasma and a co-reactant are provided in the reaction chamber during the deposition process.

6. The method for selectively forming the film of claim 5, wherein the first plasma comprises a single-frequency plasma, and the co-reactant comprises H₂, Ar, or a combination thereof.

7. The method for selectively forming the film of claim 5, wherein the first plasma comprises a combination of a first sub-plasma and a pulsed second sub-plasma, the co-reactant comprises H₂, Ar, or a combination thereof, and the first sub-plasma is different from the pulsed second sub-plasma.

8. The method for selectively forming the film of claim 5, wherein, in the etching process, an etching rate of the material layer on the second horizontal surface of the bottom portion of the gap feature is about twice an etching rate of the material layer on the vertical sidewall of the gap feature.

9. The method for selectively forming the film of claim 1, further comprising performing a treatment process after the deposition process and before the etching process.

10. The method for selectively forming the film of claim 9, wherein a first plasma is provided in the reaction chamber during the deposition process, a second plasma is provided in the reaction chamber during the treatment process, and the first plasma is different from the second plasma.

11. The method for selectively forming the film of claim 10, wherein the second plasma comprises a combination of a first sub-plasma and a second sub-plasma, and the first sub-plasma is different from the second sub-plasma.

12. The method for selectively forming the film of claim 11, wherein a co-reactant is provided in the reaction chamber during the treatment process, and the co-reactant comprises H₂, Ar, or a combination thereof.

13. The method for selectively forming the film of claim 11, wherein, in the etching process, an etching rate of the material layer on the second horizontal surface of the bottom portion of the gap feature is about 3 times an etching rate of the material layer on the vertical sidewall of the gap feature.

14. The method for selectively forming the film of claim 10, wherein the first plasma comprises a first combination of a first sub-plasma and a second sub-plasma, the second plasma comprises a second combination of a third sub-plasma and a fourth sub-plasma, and the first sub-plasma, the second sub-plasma, the third sub-plasma and the fourth sub-plasma are different.

15. The method for selectively forming the film of claim 14, wherein the second sub-plasma of the first combination of the first plasma is a pulsed plasma.

16. The method for selectively forming the film of claim 14, wherein a co-reactant is provided in the reaction chamber during the treatment process, and the co-reactant comprises H₂, Ar, or a combination thereof.

17. The method for selectively forming the film of claim 14, wherein, in the etching process, an etching rate of the material layer on the second horizontal surface of the bottom portion of the gap feature is about 4 times an etching rate of the material layer on the vertical sidewall of the gap feature.

18. The method for selectively forming the film of claim 10, wherein a frequency of the first plasma is greater than a frequency of the second plasma.

19. The method for selectively forming the film of claim 10, wherein the first plasma densifies the material layer on the vertical sidewall of the gap feature.

20. The method for selectively forming the film of claim 10, wherein the second plasma damages the material layer on the first horizontal surface and the material layer on the second horizontal surface of the bottom of the gap feature such that the material layer on the first horizontal surface and the material layer on the second horizontal surface of the bottom of the gap feature are removed during the etching process.

21. A reaction system, comprising:
a reaction chamber;
a substrate support located in the reaction chamber and configured to support a substrate;
a precursor source providing a precursor into the reaction chamber;
a co-reactant source providing a co-reactant into the reaction chamber;
a plasma power source providing a plasma into the reaction chamber; and
a controller configured to control the precursor, the co-reactant, and the plasma so as to perform the method as claimed in claim 1.
